(19) United States
(12) Patent Application Publication
(10) Pub. No.: US 2022/0190178 A1
(43) Pub. Date: Jun. 16, 2022

(54) SOLAR CELL MODULE HAVING EXCELLENT VISIBILITY

(71) Applicant: KOREA UNIVERSITY RESEARCH AND BUSINESS FOUNDATION, Seoul (KR)

(72) Inventors: Yoonmook KANG, Seoul (KR); Donghwan KIM, Yangpyeong-gun Gyeonggi-do (KR); Haeseok LEE, Seoul (KR); Yongseok JUN, Seoul (KR)

(21) Appl. No.: 17/682,293

(22) Filed: Feb. 28, 2022

Related U.S. Application Data
(63) Continuation of application No. PCT/KR2020/007967, filed on Jun. 19, 2020.

(30) Foreign Application Priority Data
Aug. 27, 2019 (KR) 10-2019-0104959

(51) Int. Cl. H01L 31/0475; H01L 31/0445; H02S 40/34; H01L 31/18

(52) U.S. Cl. CPC H01L 31/0475; H01L 31/1868; H02S 40/34; H01L 31/0445

(57) ABSTRACT

Provided, according to the present invention, is a solar cell module having excellent visibility, the solar cell module comprising: a transparent substrate; and a solar cell which is installed inside the transparent substrate and converts sunlight into photoelectricity, wherein the solar cell is installed so as to be horizontally arrayed in the transparent substrate.

### CROSS-REFERENCE TO RELATED APPLICATION

The application is a Continuation of International Patent Application No. PCT/KR2020/007967 filed on Jun. 19, 2020, which is based on and claims priority to Korean Patent Application No. 10-2019-0104959 filed on Aug. 27, 2019, which are incorporated herein by reference in their entireties.

### TECHNICAL FIELD

The present invention relates to a solar cell module having an excellent visibility, and more particularly, to a solar cell module having an excellent visibility, in which solar cells are installed in a horizontal arrangement on a transparent substrate or a transparent substrate bonded to glass, thereby improving light collection rates of visible light, near infrared light, and ultraviolet light while not affecting transparency.

### BACKGROUND ART

In general, solar systems, which are systems that convert light energy into electrical energy using solar cells, are used as independent power sources generally for homes or industries or used as auxiliary power sources in connection with commercial alternating current (AC) power systems.

Such solar systems are semiconductor elements that convert light energy into electrical energy using the photoelectric effect and each include two semiconductor thin films having a positive (+) polarity and a negative (−) polarity, a plurality of solar cells are connected in series or parallel to generate a voltage and a current required by a user, and the user may use power generated by these solar cells.

A grid-connected solar system used as a commonly used exterior building type includes a plurality of solar panels that convert solar energy into electrical energy, an inverter that converts, into AC power, direct current (DC) power that is the electrical energy converted by the solar panels and supplies the AC power to a place of use, and the like.

In such a solar system, installation of the solar panels that is installed to obtain solar energy is the most important factor in a configuration of the system, and such solar panels are installed on a separately secured site, a roof of a building, or the like.

Thus, a separate space should be secured to install the solar system in the building. In general, a cooling tower constituting a cooling apparatus is installed in the roof of the building. Thus, a place in which the solar panels are installed is narrow and limited, and the installation of the solar panels is limited, and installation work becomes difficult.

In compensate for these disadvantages, there is a case in which the solar system is applied to a window and door system installed for lighting and ventilation of the building.

That is, Korean Patent Registration No. 10-0765965 discloses a window and door using a solar cell.

The window and door using a solar cell according to the related art will be described with reference to FIG. 1.

FIG. 1 is a perspective view of a window and door according to the related art.

Referring to FIG. 1, a window and door 20 according to the related art includes a solar panel 1 that converts solar energy into electrical energy and a frame 4 coupled to an edge of the solar panel 1 and fixedly mounted on an opening 3 of a building wall 2.

That is, the window and door 20 according to the related art has a structure in which the solar panel 1 is fixed to an inner central part of the frame 4 having a rectangular shape and an outer glass window located outside the building wall 2 and an inner glass window located inside the building wall 2 are fixedly arranged on a front surface and a rear surface of the solar panel 1 to be spaced apart from the solar panel 1 by a predetermined distance.

On the other hand, when most of windows and doors are installed, devices such as window shades and verticals may be separately installed to protect privacy, and accordingly, considerable costs are required.

In this way, in the related art, the window and door and the window shades are separately present, which is not efficient in terms of cost or space.

In recent years, a method in which the window shade is directly attached to a glass of the building and installed has been proposed.

That is, as illustrated in FIGS. 2 and 3, a solar cell module 10 is manufactured by arranging a plurality of solar cells 11 made of a single crystal or a polycrystal between reinforced glass substrates 12a and 12b and attaching the solar cells 11 to each other using an ethylene vinyl acetate (EVA) film 13.

The solar cell module 10 manufactured as described above generally has a blue or black front surface as illustrated in (a) of FIG. 3 and has an almost gray rear surface as illustrated in (b) of FIG. 3.

In the solar cell module 10 according to the related art, to form an electrode wire 13b on the rear surface of the solar cell 11, two electrode wires having a width of 3-5 mm are screen-printed with silver paste (Ag) and dried in a roll conveyor equipped with an infrared lamp. The color of the electrode wire 13b dried in this way is close to light gray.

Such solar cells 11 are made by depositing an N layer on a P-type wafer or depositing a P layer on an N-type wafer. When the P-type water is used, the rear surface of each solar cell 11 has a positive (+) electrical polarity, and the front surface thereof has a negative (−) electrical polarity.

When the solar cell module 10 is made using the solar cells 11, the respective solar cells 11 are connected in series or parallel.

In this case, an interconnector ribbon 14 is used to connect the solar cells 11, and the material of the interconnector ribbon 14 is generally Sn+Pb+Ag, Sn+Ag, and Sn+Ag+Cu. When the solar cells 11 are connected in series, a silver paste electrode wire 13a formed on the front surface of the solar cell 11, having a width of 1-3 mm, and having a negative (−) polarity is connected to, through the interconnector ribbon 14, the silver paste electrode wire 13b formed on the rear surface of another solar cell, having a width of 3-5 mm, and having a positive (+) polarity.

In this way, the interconnector ribbon 14 connecting the solar cells 11 has a width of 1.5-3 mm and a thickness of 0.01-0.2 mm.

Examples of a connection method thereof include an indirect connection method using an infrared lamp, a halogen lamp, and hot air and a direct connection method using a soldering iron.

Meanwhile, the EVA film 13 located between the glass substrates 12a and 12b of the solar cell module 10 starts to be melted at a temperature of 80 degrees, becomes clear and transparent at a temperature of 150 degrees, and thus bonds the solar cell 11 and the glass substrates. Further, the EVA film 13 prevents the penetration of moisture and air from the outside toward the solar cell 11 to prevent corrosion or short circuit of the silver paste electrode wires 13a and 13b of the solar cell 11.

The EVA film 13 is melted between the double bonded glass substrates 12a and 12b of the solar cell module 10 when being laminated by a laminator (not illustrated), and thus becomes clear and transparent. In this case, the other parts except for the solar cell 11 and the interconnector ribbon 14 are transparent.

The building integrated photovoltaic (BIPV) solar cell module 10 according to the related art is manufactured using a single crystal or polycrystal solar cell 11, is disposed between the double glass substrates 12a and 12b of the building, and thus is visible from inside and outside the building.

As described above, the solar cell module 10 mounted on the building has a front surface that is colored in a process of forming electrodes by plasma-enhanced chemical vapor deposition (PECVD) and atmospheric pressure chemical vapor deposition (APCVD)(not illustrated) that are vacuum apparatuses and depositing an anti-reflection film by screen printing. In general, the front surface has a blue color or a black color, but a back surface field (BSF) of the solar cell module 10 is deposited by a vacuum apparatus (not illustrated) with aluminum (Al) to form an electrode, and thus has a gray color.

Further, in the solar cell module 10 as describe above according to the related art, several to tens of the solar cells 11 are connected inside the glass substrates (12a and 12b) using the interconnector ribbon 14, and these interconnector ribbons 14 cannot maintain a constant linear line and becomes bent or serpentine.

In this state, when the solar cell module 10 is laminated and thus completed, the shape of the interconnector ribbon 14 connecting the solar cells 11 inside the glass substrates (12a and 12b) is entirely bent and is not uniform.

Further, in the solar cell module 10 according to the related art, the interconnector ribbon 14 has a silver color, and when the BIPV solar cell module 10 is manufactured, the interconnector ribbon 14 has front and rear surfaces exposed in a silver color without change.

Thus, in the solar cell module 10 according to the related art, since the rear surface thereof and the interconnector ribbon 14 have a gray color and a silver color, when a double bonded solar cell module 10 is manufactured, the silver color of the interconnector ribbon 14 is exposed to the outside through the front glass substrates 12a and 12b on the front surface of the solar cell module 10, and the gray and silver colors of the rear surface are visible without change. Further, since lines of the interconnector ribbon 14 look bent and serpentine, when the solar cell module 10 is attached as a substitute of the glass of an urban building, the outer appearance is bad.

### DETAILED DESCRIPTION OF THE INVENTION

### Techinical Problem

To solve the above problems, in a solar cell module having an excellent visibility according to the present invention, solar cells are installed in a horizontal arrangement on a transparent substrate or a transparent substrate bonded to glass, thereby improving light collection rates of visible light, near-infrared light, and ultraviolet light. Further, as the solar cells are installed at equal intervals in a vertical line direction that is an arrangement horizontal to the transparent substrate or a surface of the glass, the solar cells are installed in a range that does not interfere in a view field of a human while improving the light collection rates, and thus transparent visibility may be secured.

Further, the purpose of the present invention is to horizontally arrange the solar cells on the transparent substrate to absorb broadband visible light while a transmittance thereof is balanced.

Further, the purpose of the present invention is to implement excellent color rendering close to natural light on the basis of a high average transmittance of a broadband visible light region through the solar cell.

Further, the purpose of the present invention is to install the plurality of light collection modules in a space between the solar cells inside the transparent substrate to absorb light on a plate including a light emitter for re-emitting absorbed light so as to improve light absorption efficiency.

### Technical Solution

An aspect of the present invention provides a solar cell module having an excellent visibility, including a transparent substrate, and a solar cell installed inside the transparent substrate to convert sunlight into photoelectricity, wherein the solar cell is installed on the transparent substrate in a horizontal arrangement.

Another aspect of the present invention provides a solar cell module having an excellent visibility, including a glass, a transparent substrate surface-bonded to the glass, and a solar cell installed in a groove formed in one surface of the transparent substrate to convert sunlight into photoelectricity, wherein the solar cell is installed on the transparent substrate in a horizontal arrangement.

Still another aspect of the present invention provides a solar cell module having an excellent visibility, including a glass, a solar cell installed on one surface of the glass to convert sunlight into photoelectricity, and a transparent substrate impregnated with the solar cell by resin molding on the one surface of the glass, wherein the solar cell is installed on the transparent substrate in a horizontal arrangement.

Yet another aspect of the present invention provides a solar cell module having an excellent visibility, including a glass, a solar cell that is laminated on one surface of the glass, is installed on a surface of the glass in a horizontal arrangement by wet etching the remaining portion except for an etching mask printed portion, and converts sunlight into photoelectricity, and a transparent substrate solidified by impregnating the solar cell by resin molding on the one surface of the glass.

According to the present invention, the horizontal arrangement may mean that the solar cell is installed in a vertical line direction between −10° to 10° with respect to a front surface of the erected transparent substrate.

According to the present invention, the horizontal arrangement may mean that the solar cell is installed in a vertical line direction between −10° to 10° with respect to a front surface of the glass.

According to the present invention, the solar cell may be provided as a plurality of solar cells installed at equal intervals.

According to the present invention, the solar cell may be provided as a plurality of solar cells installed on the transparent substrate at equal intervals, and a plurality of light collection modules may be arranged and installed between the solar cells.

According to the present invention, the transparent substrate and the glass may be surface-bonded to each other.

According to the present invention, a light emitting diode (LED) light emitting body may be installed in the solar cell.

According to the present invention, a solar cell for a thin film solar cell type having a thickness of 10 nm to 10 μm may be applied to the solar cell.

According to the present invention, a solar cell for a double-sided light receiving silicon solar cell type having a thickness of 50 μm to 300 μm may be applied to the solar cell.

According to the present invention, a thin film layer expressing a color may be installed in the solar cell.

According to the present invention, a transparent electrode may be installed between the transparent substrate and the glass to be electrified with the solar cell.

According to the present invention, a light absorption layer may be coated between the transparent substrate and the glass and on the solar cell.

According to the present invention, a thin film layer expressing a color may be installed in a bonding surface of the transparent substrate bonded to the glass.

According to the present invention, a passivation or an anti-reflection layer is further included at a front end of the solar cell.

### Advantageous Effects of the Invention

As described above, in a solar cell module having an excellent visibility of the present invention, solar cells are installed in a vertical line direction on a transparent substrate or a transparent substrate bonded to a glass, and thus visible light, near-infrared light, and ultraviolet light are transmitted through the transparent substrate. At the same time, the solar cells are installed in a horizontal arrangement to improve a light collection rate in accordance with an optimal incident angle of sunlight. At the same time, the solar cells are installed in a range that does not interfere in a view field of a human, and thus a function of the solar cell having improved light collection efficiency may be performed while transparent visibility is secured.

Further, the solar cell module having an excellent visibility of the present invention may absorb broadband visible light, while a transmittance thereof is balanced, through a transparent substrate on which the solar cells are horizontally arranged at equal intervals.

Further, the solar cell module having an excellent visibility of the present invention may implement excellent color rendering close to natural light on the basis of a high average transmittance of a broadband visible light region through the solar cell.

Further, in the solar cell module having an excellent visibility of the present invention, the plurality of light collection modules are installed in a space between the solar cells inside the transparent substrate, light is absorbed on a plate including a light emitter for re-emitting absorbed light, and thus light absorption efficiency is improved.

Further, since the solar cell module having an excellent visibility of the present invention may be applied to a window in addition to a roof and a wall of a building, the solar cell module may be applied to a building of which an outer wall is applied as the window in addition to existing installation places such as the roof or the wall, and thus as much power as solar units may be obtained.

### DESCRIPTION OF THE DRAWINGS

FIG. 1 is a perspective view of a window and door according to a related art.

FIG. 2 is a cross-sectional view illustrating a solar cell module according to the related art.

FIG. 3 shows a front view and a rear view illustrating the solar cell module according to the related art.

FIG. 4 is a perspective view illustrating a solar cell module according to a first embodiment of the present invention.

FIGS. 5A and 5B are each a cross-sectional view illustrating the solar cell module according to the first embodiment of the present invention.

FIG. 6 is a perspective view illustrating a solar cell module according to a second embodiment of the present invention.

FIG. 7 is a cross-sectional view illustrating the solar cell module according to the second embodiment of the present invention.

FIG. 8 is a cross-sectional view illustrating a state in which a light collection module is applied to the solar cell module according to the second embodiment of the present invention.

FIG. 9A is a diagram illustrating an arrangement state of solar cells of the solar cell module of the present invention.

FIG. 9B is a graph depicting a transmittance of visible light that are shown when a near-infrared mirror is applied to the solar cell module of the present invention, FIG. 9C is a graph depicting a collection rate of near-infrared rays that are shown when a near-infrared mirror is applied to the solar cell module of the present invention.

FIG. 10A and FIG. 10B are a diagram illustrating an arrangement state of the solar cell and the light collection module of the solar cell module of the present invention.

FIG. 100 is a diagram illustrating a state of a light collection rate according to installation of the solar cell and the light collection module of the solar cell module of the present invention.

FIG. 11 is a manufacturing sequence diagram illustrating a solar cell module according to a third embodiment of the present invention.

FIG. 12 is a manufacturing sequence diagram illustrating a solar cell module according to a fourth embodiment of the present invention.

FIG. 13A, FIG. 13B, FIG. 13C, FIG. 13D, FIG. 13E, FIG. 13F and FIG. 13G are views each illustrating various application examples of a transparent substrate applied to a transparent solar cell module of the present invention.

### BEST MODE

Hereinafter, embodiments of the present invention will be described in detail with reference to the accompanying drawings.

First, it should be noted that in the drawings, the same components or parts are designated by the same reference numerals as much as possible. In description of the present invention, detailed descriptions of related widely known functions and configurations are omitted so as not to obscure the subject matter of the present invention.

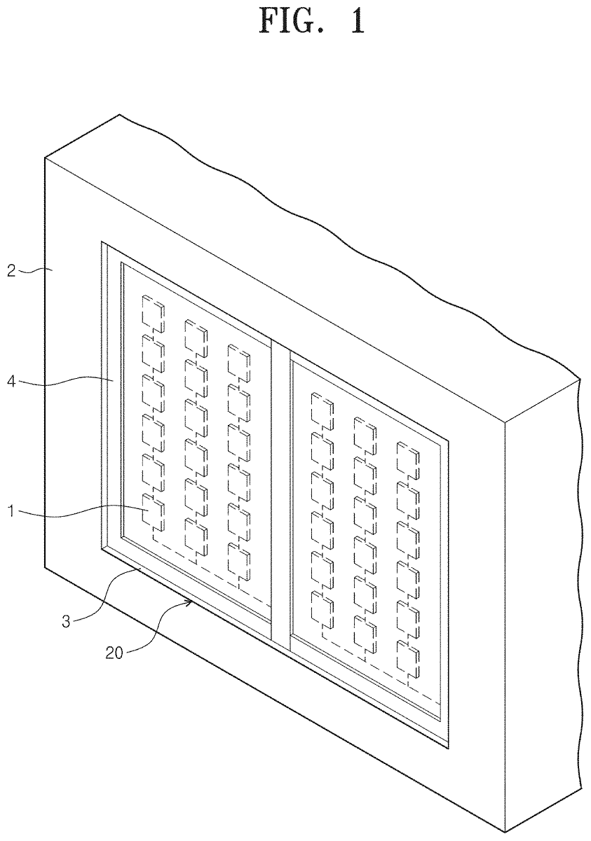

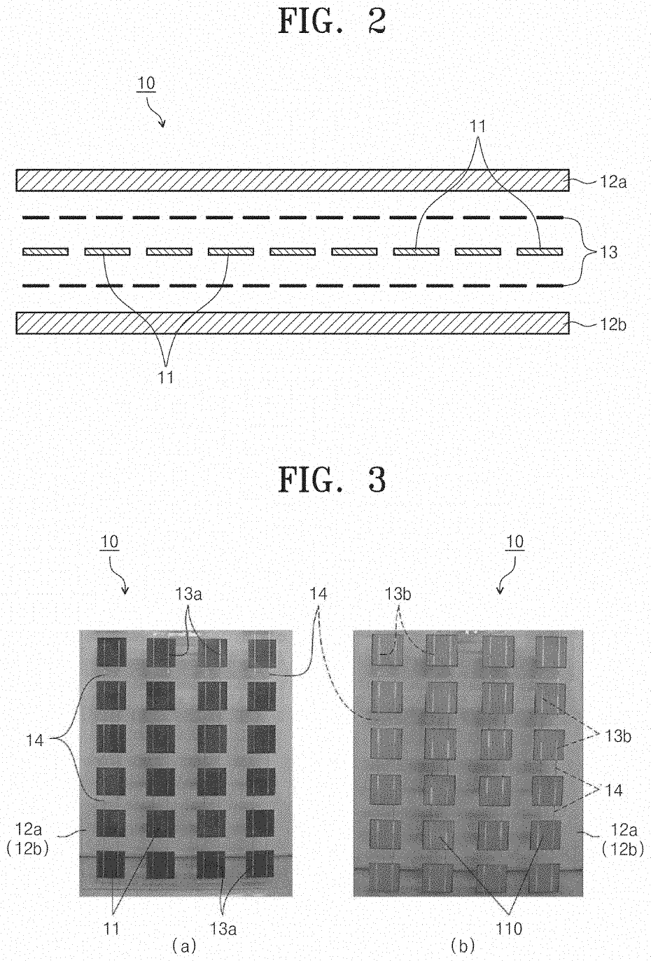

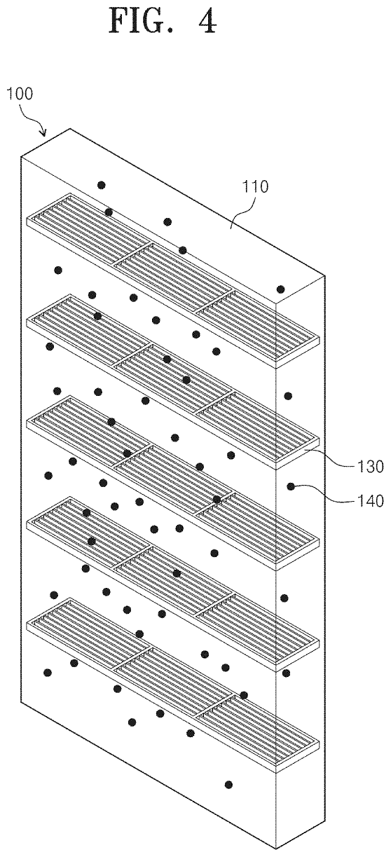

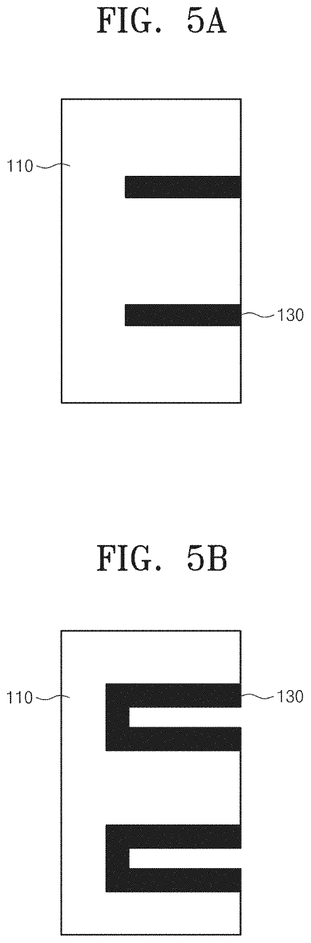

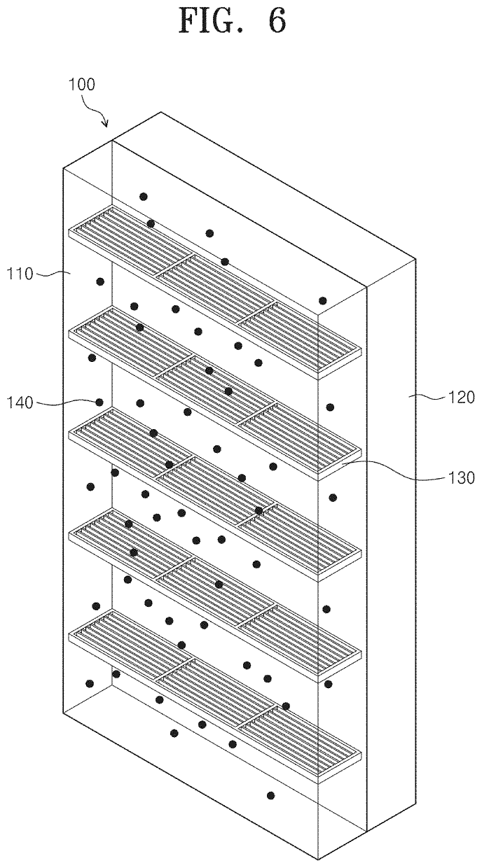

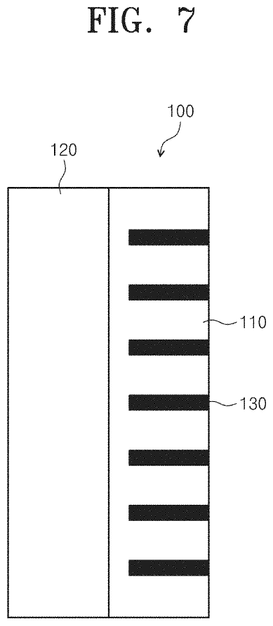

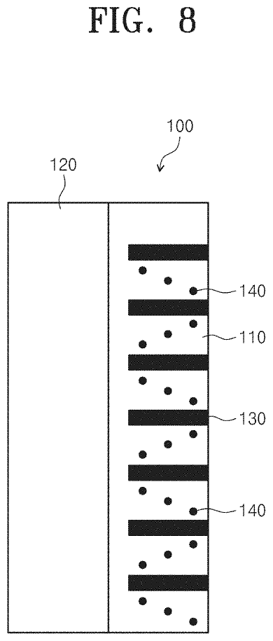

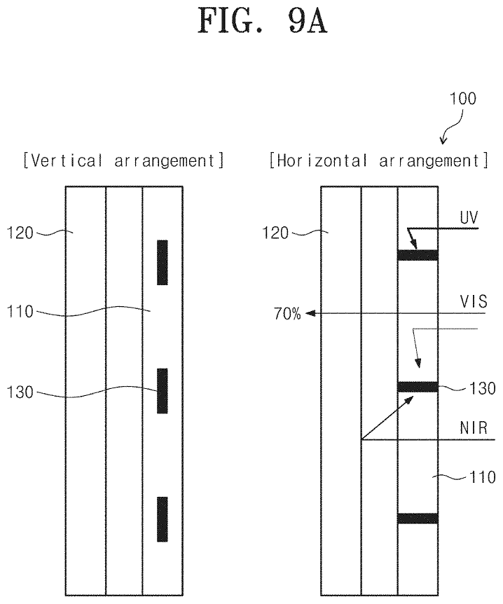

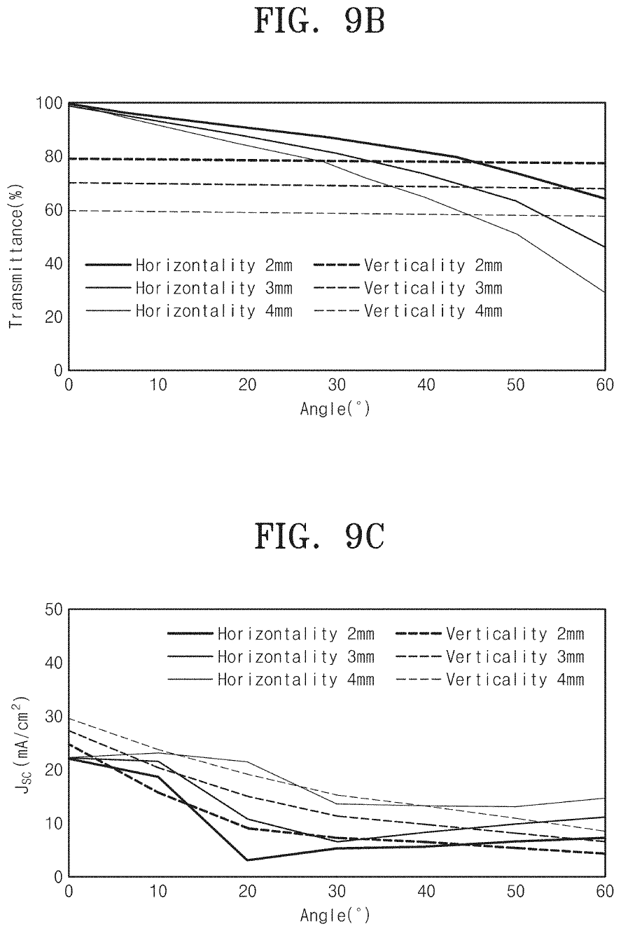

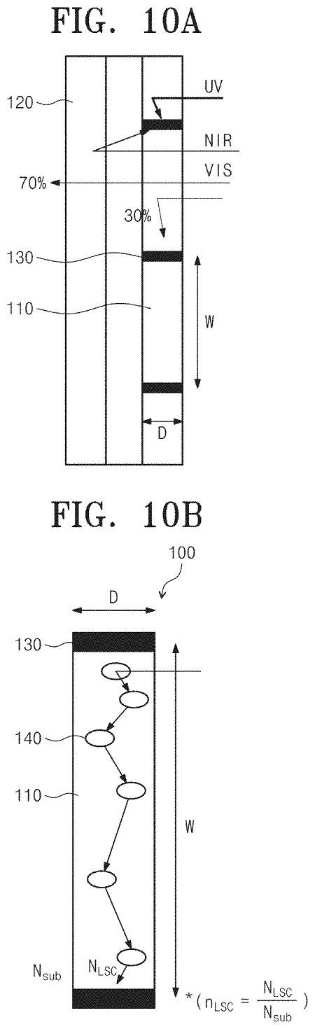

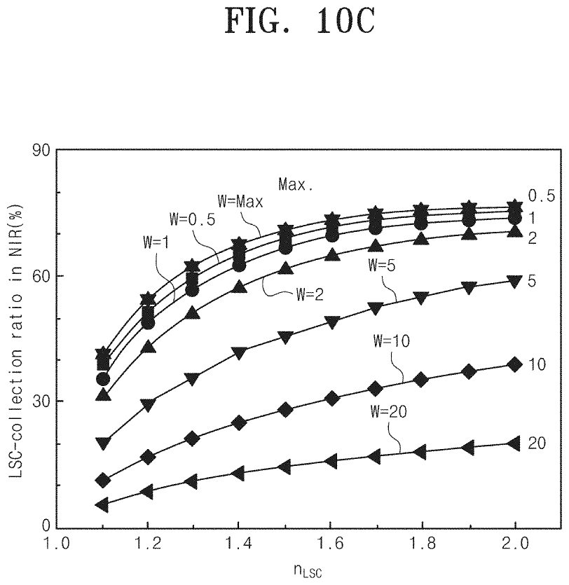

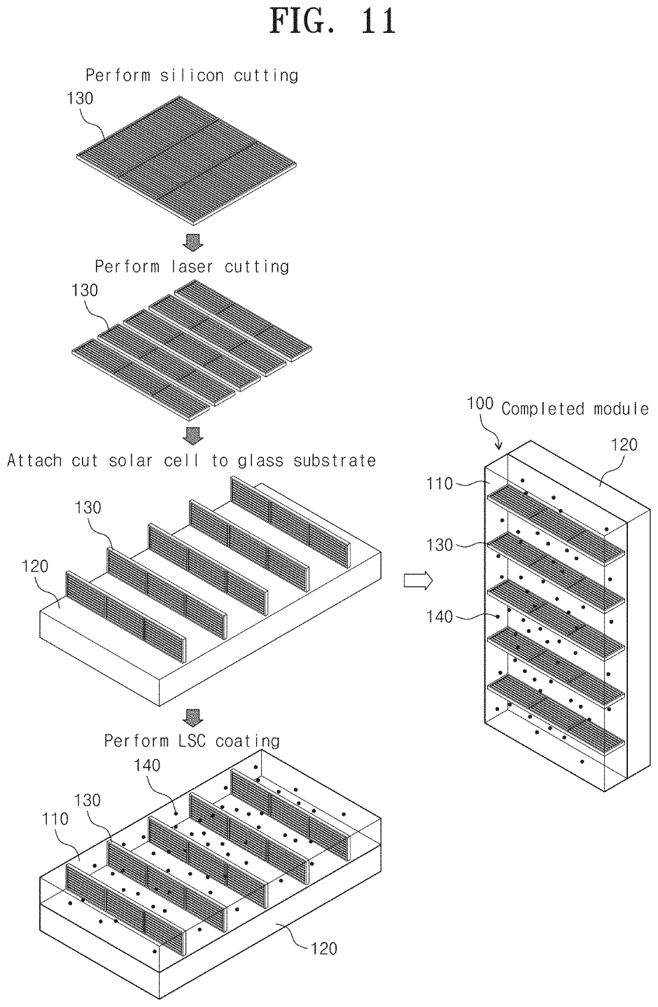

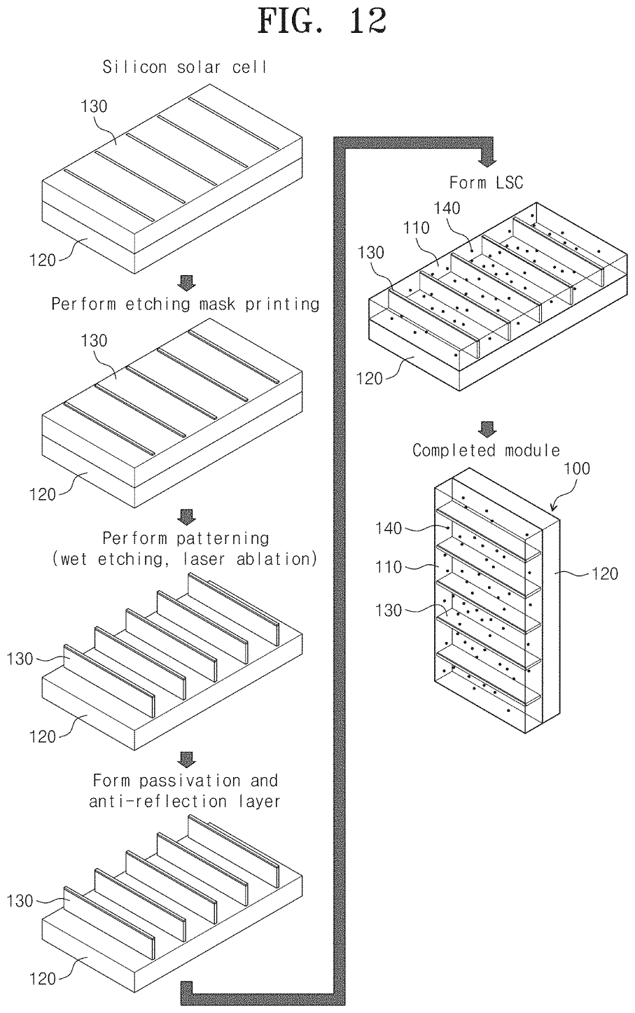

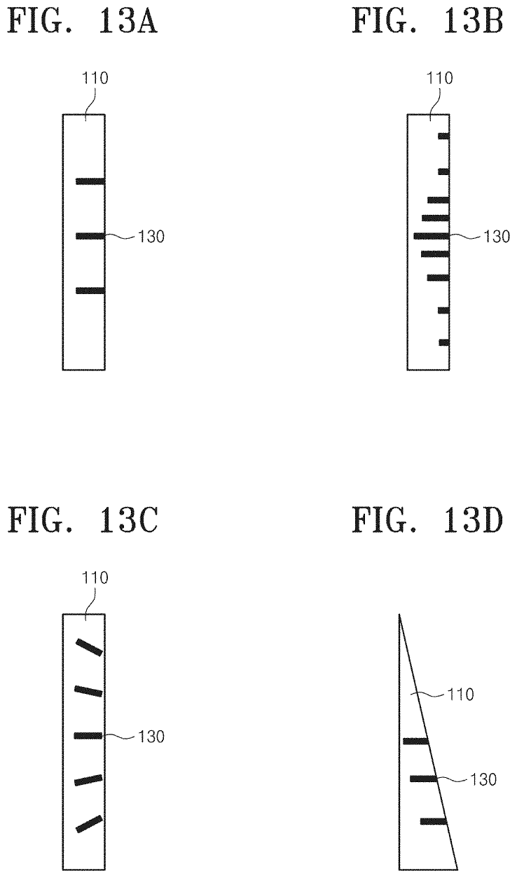

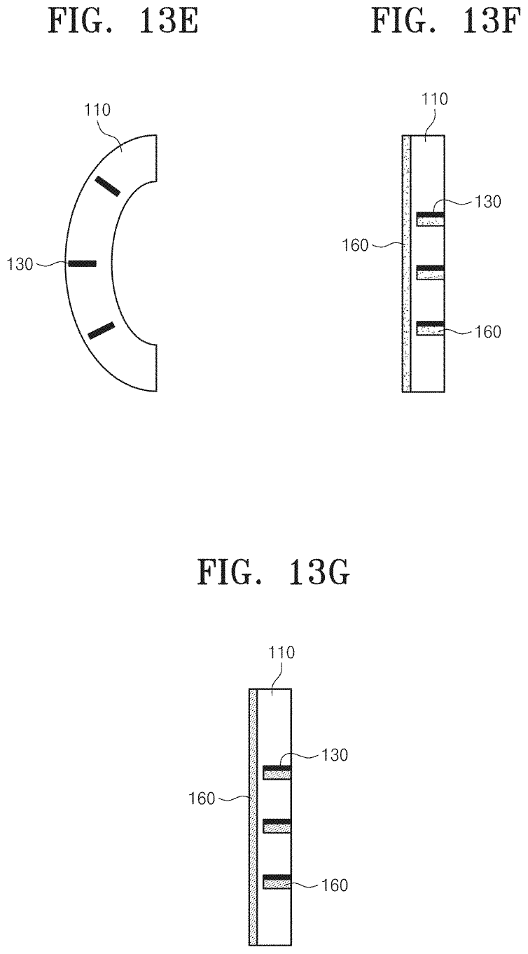

FIG. 1 is a perspective view of a window and door according to a related art, FIG. 2 is a cross-sectional view illustrating a solar cell module according to the related art, FIG. 3 shows a front view and a rear view illustrating the solar cell module according to the related art, FIG. 4 is a perspective view illustrating a solar cell module according to a first embodiment of the present invention, FIGS. 5A and 5B are each a cross-sectional view illustrating the solar cell module according to the first embodiment of the present invention, FIG. 6 is a perspective view illustrating a solar cell module according to a second embodiment of the present invention, FIG. 7 is a cross-sectional view illustrating the solar cell module according to the second embodiment of the present invention, FIG. 8 is a cross-sectional view illustrating a state in which a light collection module is applied to the solar cell module according to the second embodiment of the present invention, FIG. 9A is a diagram illustrating an arrangement state of solar cells of the solar cell module of the present invention, FIG. 9B is a graph depicting a transmittance of visible light that are shown when a near-infrared mirror is applied to the solar cell module of the present invention, FIG. 9C is a graph depicting a collection rate of near-infrared rays that are shown when a near-infrared mirror is applied to the solar cell module of the present invention, FIG. 10A and FIG. 10B are a diagram illustrating an arrangement state of the solar cell and the light collection module of the solar cell module of the present invention, FIG. 100 is a diagram illustrating a state of a light collection rate according to installation of the solar cell and the light collection module of the solar cell module of the present invention, FIG. 11 is a manufacturing sequence diagram illustrating a solar cell module according to a third embodiment of the present invention, FIG. 12 is a manufacturing sequence diagram illustrating a solar cell module according to a fourth embodiment of the present invention, FIG. 13A, FIG. 13B, FIG. 13C, FIG. 13D, FIG. 13E, FIG. 13F and FIG. 13G are views each illustrating various application examples of a transparent substrate applied to a transparent solar cell module of the present invention.

In a solar cell module 100 of the present invention, a solar cell 130 is installed on a transparent substrate, visible light, near infrared light, and ultraviolet light are transmitted through the substrate, and the solar cell 130 is installed in a horizontal arrangement on the substrate and is installed in a range that does not interfere in a range of a view field.

Thus, a transmittance of the sunlight and a visibility of naked eyes may be secured through a transparent substrate 110.

Here, the solar cell 130 of a thin film solar cell type, having a thickness of 10 nm to 10 μm, may be applied to the solar cell 130 or a solar cell 130 for a double-sided light receiving silicon solar cell type, having a thickness of 50 to 300 μm, may be applied to the solar cell 130.

In detail, types of the solar cell 130 applied in the present invention is not limited.

The thin film solar cell may be variously classified according to a thin film deposition temperature, the type of a substrate used, and a deposition method and may be roughly classified into an amorphous silicon thin film solar cell and a crystalline silicon thin film solar cell according to crystal characteristics of a light absorption layer.

The amorphous silicon (a-Si) solar cell, which is a representative thin film solar cell, is a solar cell made by injecting amorphous silicon between substrates of a glass 120.

Further, the thin film solar cell may be manufactured in a multi-junction structure such as a double junction in which a polycrystalline silicon film is further laminated on an amorphous silicon thin film and a triple junction in which one silicon film is further laminated thereon or may be manufactured in a hybrid structure, thereby improving conversion efficiency.

In addition, the solar cell 130 for a thin film solar cell type described above may include an amorphous silicon thin film solar cell and a compound-based thin film solar cell, but the present invention is not limited thereto. The solar cell 130 for a double-sided light receiving silicon solar cell type may include a crystalline silicon solar cell, but the present invention is not limited thereto.

The solar cell 130 having the above characteristics is installed on the transparent substrate 110, the transparent substrate 110 to which the glass 120 is bonded, or the transparent substrate 110 molded to the glass 120 so as to have a transparent function.

Here, the solar cell 130 may be formed in the form of a plate, and the planar area of the solar cell 130 may be variously applied.

The solar cell 130 as described above is installed on the substrate in a horizontal arrangement so as not to be disturbed by an interference of an incident angle of the sunlight and is installed in range that does not interfere in a range of the view field of a human.

That is, the horizontal arrangement means that the solar cell 130 is installed in a vertical line direction between −10° and 10° on one surface of the transparent substrate 110 or the glass 120 in a vertically standing state.

Here, the one surface of the transparent substrate 110 or the glass 120 may mean a surface in which the incident light is incident.

In general, perpendicular lines refer to two linear lines, line segments, or semi-linear lines that meet each other at 90°, and linear lines that meet each other at a right angle refer to orthogonal lines.

In the present invention, the horizontal arrangement includes an angle in the range of −10° to 10° in a vertical line direction.

As described above, the solar cell 130 is inserted into the substrate in the horizontal arrangement, and the solar cell 130 is provided as a plurality of solar cells 130 installed at equal intervals.

Further, visible light, near infrared light, and ultraviolet light are transmitted through the transparent substrate 110 in a space between the solar cells 130.

Of course, light is transmitted through the transparent substrate 110, and thus a visibility is achieved, and at the same time, there is no interference of the view field through a gap between the solar cells 130, and thus a transmittance of the transparent substrate 110 is secured.

The solar cell module as described above includes four embodiments.

As illustrated in FIGS. 4, 5A and 5B, the solar cell module 100 according to a first embodiment of the present invention includes the transparent substrate 110 and the solar cell 130 installed inside the transparent substrate 110 to convert the sunlight into photoelectricity, wherein the solar cell 130 is installed on the transparent substrate 110 in the horizontal arrangement.

Further, it is preferable that the solar cell module 100 according to the first embodiment of the present invention includes a solar cell 130 selected from any one of a solar cell 130 for a thin film solar cell type and a solar cell 130 for a double-sided light receiving silicon solar cell type.

To enable this, grooves may be installed in the one surface of the transparent substrate 110 at equal intervals, the solar cell 130 may be inserted into the transparent substrate 110, and the solar cell 130 may be installed inside the transparent substrate 110.

Alternatively, when the transparent substrate 110 is manufactured by providing the solar cell 130 as a plurality of solar cells 130, by arranging the solar cells 130 in a direction perpendicular to the one surface of the transparent substrate 110, by then performing resin molding so that the solar cells 130 are impregnated, and by being solidified, the solar cells 130 may be installed inside the transparent substrate 110 in the horizontal arrangement.

Referring to FIGS. 5A and 5B, the solar cell 130 for a double-sided light receiving silicon solar cell type arranged in the direction perpendicular to the one surface of the transparent substrate 110 may have a structure illustrated in FIG. 5A, and the solar cell 130 for a thin film solar cell type in which the grooves are installed in any one surface of the transparent substrate 110 at equal intervals and the solar cell 130 is inserted into the grooves may have a structure illustrated in FIG. 5B.

The first embodiment as described above may be applied as a substitute for the glass 120 in the building using the transparent substrate 110 into which the solar cell 130 is inserted.

Further, as illustrated in FIGS. 6 to 8, the solar cell module 100 according to a second embodiment of the present invention includes the glass 120, the transparent substrate 110 surface-bonded to the glass 120, and the solar cell 130 installed in the grooves formed in the one surface of the transparent substrate 110 to convert the sunlight into the photoelectricity, wherein the solar cell 130 is installed in the transparent substrate 110 in the horizontal arrangement.

Further, it is preferable that the solar cell module 100 according to the second embodiment is the solar cell 130 for a thin film solar cell type.

To enable this, the grooves may be installed in the one surface of the transparent substrate 110 at equal intervals, the solar cell 130 may be inserted into the transparent substrate 110, and the solar cell 130 may be installed inside the transparent substrate 110.

The transparent substrate 110 having the solar cell 130 manufactured in this way has the advantages in that the transparent substrate 110 may be applied to the window and door while performing a transparent function by being bonded to the glass 120, and at the same time, may improve efficiency of thermal insulation energy.

In addition, as illustrated in FIG. 4 of the first embodiment and FIGS. 6 and 8 of the second embodiment, the transparent substrate 110 is generally manufactured in a resin molding method. In this case, in the resin molding method, when a plurality of light collection modules 140 are mixed and solidified, and thus the transparent substrate 110 is manufactured, the plurality of light collection modules 140 may be installed between the solar cells 130.

Further, FIG. 9A is a cross-sectional view illustrating the solar cell module 100 in a state in which the solar cells 130 are arranged in a vertical arrangement or the horizontal arrangement, FIG. 9B, and FIG. 9C are a graph depicting the transmittance (FIG. 9B) of visible light and a collection amount (FIG. 9C) of near-infrared light which are shown when the near-infrared mirror is applied to the solar cell module 100.

In the present invention, the solar cell module 100 in a state in which the solar cells 130 are arranged in the vertical arrangement or the horizontal arrangement may further include the near-infrared mirror, the light collection module 140, and the like to improve light efficiency.

Referring to the FIG. 9B, it may be identified that, after the solar cells 130 are arranged in the horizontal arrangement, even when a horizontal length of the solar cells 130 is changed, the transmittance of visible light does not change according to an incident angle. Further, it may be identified that, when the solar cells 130 are arranged in the vertical arrangement, the transmittance of visible light decreases as the incident angle increases, and significantly decreases as a vertical length of the solar cells 130 increases.

In addition, referring to the FIG. 9C, it may be identified that, when the solar cells 130 are arranged in the horizontal arrangement, the collection amount J_{sc} of near-infrared light increases as the incident angle increases, and the collection amount J_{sc} of near-infrared light increases as the horizontal length of the solar cells 130 increases.

[Table 1] below illustrates the collection amount J_{sc} and the light collection rate of near-infrared light according to the vertical arrangement or the horizontal arrangement of the solar cell 130 when the incident angle is 0 degrees and when both the near-infrared mirror and the light collection module 140 are applied to the solar cell module 100.

TABLE 1

| | Incident angle of 0 degrees | | | | | |
|---|---|---|---|---|---|---|
| | Horizontality | Horizontality | Horizontality | Verticality | Verticality | Verticality |
| | 2 mm | 3 mm | 4 mm | 2 mm | 3 mm | 4 mm |
| Jsc(mA/cm²) | 26.2 | 26.4 | 26.4 | 28.8 | 31.3 | 33.5 |
| Light | 3.6 | 2.4 | 1.8 | 4 | 2.9 | 2.3 |
| collection | | | | | | |
| rate | | | | | | |

[Table 2] below illustrates the collection amount J_{sc} and the light collection rate of near-infrared light according to the vertical arrangement or the horizontal arrangement of the solar cell 130 when the incident angle is 0 degrees and when neither the near-infrared mirror nor the light collection module 140 are applied to the solar cell module 100.

TABLE 2

| | Incident angle of 0 degrees | | | | | |
|---|---|---|---|---|---|---|
| | Horizontality | Horizontality | Horizontality | Verticality | Verticality | Verticality |
| | 2 mm | 3 mm | 4 mm | 2 mm | 3 mm | 4 mm |
| Jsc(mA/cm²) | 13.73 | 16.78 | 21.3 | 14.4 | 18.0 | 21.2 |
| Light | 1.9 | 1.6 | 1.5 | 2 | 1.7 | 1.5 |
| collection | | | | | | |
| rate | | | | | | |

As in [Table 1] and [Table 2], it may be identified that, as both the near-infrared mirror and the light collection module 140 are applied to the solar cell module, the collection amount J_{sc} and the light collection rate of near-infrared light are increased.

Further, as illustrated in FIGS. 10A, 10B and 100, in the solar cell module 100, as an interval W between the solar cells 130 increases, a loss occurs from scattering, re-radiation, and re-absorption of the sunlight, and thus the light collection rate of near-infrared light may be reduced by 20% or more.

That is, in the present invention, the plurality of light collection modules 140 are installed between the solar cells 130, and thus the light collection rate of near-infrared light may be improved.

Further, as illustrated in FIGS. 11 to 13G, the solar cell module 100 according to a third embodiment of the present invention includes the glass 120, the solar cell 130 installed on one surface of the glass 120 to convert the sunlight into photoelectricity, and the transparent substrate 110 impregnated with the solar cell 130 by resin molding on the one surface of the glass 120, wherein the solar cell 130 is installed on the transparent substrate 110 in the horizontal arrangement.

Further, it is preferable that the solar cell module 100 according to the third embodiment is the solar cell 130 for a double-sided light receiving silicon solar cell type.

That is, when the transparent substrate 110 is manufactured by providing the solar cell 130 as a plurality of solar cells 130, by arranging the solar cells 130 in a direction perpendicular to the one surface of the glass 120, by then performing resin molding so that the solar cells 130 are impregnated, and by being solidified, the solar cells 130 are vertically installed in the horizontal arrangement inside the transparent substrate 110.

Here, in the resin mold, when the transparent substrate 110 is manufactured by mixing and solidifying the plurality of light collection modules 140, the plurality of light collection modules 140 are installed between the solar cells 130.

Here, the light collection module 140 is also referred to as a Luminescent solar concentrator(LSC). Unlike general solar cells that generally and directly absorb the sunlight to convert the absorbed sunlight into electricity, the light collection module 140 absorbs light on a plate including a light emitter that re-emits light absorbed at a long wavelength.

A light emitting diode (LED) light emitting body may be installed at a lower end of the solar cell 130 applied to the first embodiment, the second embodiment, and the third embodiment as described above.

This makes it possible to achieve consumer-customized designs by emitting a variety of light through the LED light emitting body.

Alternatively, the solar cell 130 may further include a thin film layer 160 expressing a color, and the thin film layer 160 expressing a color may be installed on a bonding surface, of the transparent substrate 110, bonded to the glass 120.

Therefore, various function for controlling a transmittance, a color, or color rendering or for privacy protection may be performed through a transparent solar cell.

As illustrated in FIG. 12, the solar cell module 100 according to the fourth embodiment of the present invention includes the glass 120, the solar cell 130 which is laminated on the one surface of the glass, is installed on the surface of the glass 120 in the horizontal arrangement by wet etching the remaining portion except for an etching mask printed portion, and converts the sunlight into photoelectricity, and the transparent substrate 110 solidified by impregnating the solar cell 130 by resin molding on the one surface of the glass 120.

Further, it is preferable that the solar cell module 100 according to the fourth embodiment is the solar cell 130 for a double-sided light receiving silicon solar cell type.

That is, in a state in which the glass 120 and the solar cell 130 are bonded, etching mask printing is performed on upper surfaces of the solar cells 130 arranged at equal intervals.

Thereafter, a portion except for the etching mask printed portion is etched through a wet etching process.

Therefore, the solar cell 130 is provided as a plurality of solar cells 130 arranged at equal intervals.

In this case, the solar cell 130 is in a state of being erected in a direction perpendicular to the surface of the glass 120.

Further, a passivation or an anti-reflection layer is formed at a front end of the solar cell 130 to protect the solar cell 130.

In this way, when the transparent substrate 110 is manufactured by arranging the solar cells 130 in the direction perpendicular to the surface of the glass 120, by then performing resin molding so that the solar cells 130 are impregnated, and by being solidified, the solar cells 130 are installed inside the transparent substrate 110.

As described above, the plurality of light collection modules 140 are arranged between the solar cells 130 described in the first to fourth embodiments to absorb light passing through the transparent substrate 110 so as to improve light efficiency.

Further, in the first to fourth embodiments, a transparent electrode is installed between the transparent substrate 110 and the glass 120 to be electrified with the solar cell 130.

Further, in the first to fourth embodiments, a light absorption layer may be coated between the transparent substrate 110 and the glass 120 and on the solar cell 130.

Here, the already arranged solar cell 130 may be a first solar cell, and the light absorption layer may include a second solar cell different from the first solar cell.

In particular, as illustrated in FIGS. 13A to 13G, the transparent substrate 110 manufactured through the first to fourth embodiments has a cross-section shape that may be freely changed.

Further, the solar cells 130 are freely arranged in accordance with the cross-sectional shape of the transparent substrate 110.

In this way, in the solar cell module 100 of the present invention, the solar cell 130 is vertically installed in the transparent substrate 110 or the transparent substrate bonded to the glass 120, and thus visible light, near-infrared light, and ultraviolet light are transmitted through the transparent substrate 110. At the same time, the solar cells 130 are vertically installed at equal intervals, and thus are installed in a range that does not interfere in a view field. Thus, the solar cell module 100 is transparent and may perform a solar cell function.

Further, in a state in which a broadband visible light transmittance is balanced, light may be absorbed through the transparent substrate 110 in which the solar cells 130 are vertically arranged at equal intervals.

Further, excellent color rendering close to natural light is implemented on the basis of a high average transmittance of a broadband visible light region through the solar cell.

Further, the plurality of light collection modules 140 are installed in the space between the solar cells 130 inside the transparent substrate 110 to absorb light on the plate including the light emitter for re-emitting absorbed light so as to improve light absorption efficiency.

Further, since the solar cell module 100 may be applied to the window in addition to the roof and the wall of the building, the solar cell module 100 may be applied to a building of which an outer wall is applied as the window in addition to existing installation places such as the roof or the wall, and thus as much power as solar units is obtained.

The present invention described above is not limited by the above-described embodiments and the accompanying drawings, and it is apparent to those skilled in the art to which the present invention belongs that various substitutes, modifications, and changes may be made without departing from the technical spirit of the present invention.

1. A solar cell module having an excellent visibility, comprising:
a transparent substrate; and
a solar cell installed inside the transparent substrate to convert sunlight into photoelectricity,
wherein the solar cell is installed on the transparent substrate in a horizontal arrangement.

2. The solar cell module of claim 1, further comprising: a glass surface-bonded to the transparent substrate;
wherein the solar cell is installed in a groove formed on one surface of the transparent substrate to convert sunlight into photoelectricity.

3. The solar cell module of claim 2, wherein the solar cell is installed on one surface of the glass to convert sunlight into photoelectricity; and
the transparent substrate is impregnated with the solar cell by resin molding on the one surface of the glass. 20

4. The solar cell module of claim 1, further comprising:
the solar cell that is laminated on one surface of the glass, is installed on a surface of the glass in a horizontal arrangement by wet etching the remaining portion except for an etching mask printed portion, and converts sunlight into photoelectricity;
wherein the transparent substrate solidified by impregnating the solar cell by resin molding on the one surface of the glass.

5. The solar cell module of claim 1, wherein the horizontal arrangement means that the solar cell is installed in a vertical line direction between −10° to 10° with respect to one surface of the erected transparent substrate.

6. The solar cell module of claim 4, wherein the horizontal arrangement means that the solar cell is installed in a vertical line direction between −10° to 10° with respect to the one surface of the glass.

7. The solar cell module of claim 1, wherein the solar cell is provided as a plurality of solar cells installed at equal intervals.

8. The solar cell module of claim 1, wherein the solar cell is provided as a plurality of solar cells installed on the transparent substrate at equal intervals, and
wherein a plurality of light collection modules are arranged and installed between the solar cells.

9. The solar cell module of claim 1, wherein the transparent substrate and the glass are surface-bonded to each other.

10. The solar cell module of claim 1, wherein a light emitting diode (LED) light emitting body is installed in the solar cell.

11. The solar cell module of claim 1, wherein a solar cell for a thin film solar cell type having a thickness of 10 nm to 10 μm is applied to the solar cell.

12. The solar cell module of claim 1, wherein a solar cell for a double-sided light receiving silicon solar cell type having a thickness of 50 μm to 300 μm is applied to the solar cell.

13. The solar cell module of claim 1, wherein a thin film layer expressing a color is installed in the solar cell.

14. The solar cell module of claim 2, wherein a transparent electrode is installed between the transparent substrate and the glass to be electrified with the solar cell.

15. The solar cell module of claim 2, wherein a light absorption layer is coated between the transparent substrate and the glass and on the solar cell.

16. The solar cell module of claim 2, wherein a thin film layer expressing a color is installed in a bonding surface of the transparent substrate bonded to the glass.

17. The solar cell module of claim 4, wherein a passivation or an anti-reflection layer is further included at a front end of the solar cell.
